(19) United States
(12) Patent Application Publication
(10) Pub. No.: US 2025/0157796 A1
(43) Pub. Date: May 15, 2025

(54) PROCESSING CHAMBER WITH A ROTATABLE PEDESTAL HUB

(71) Applicant: Applied Materials, Inc., Santa Clara, CA (US)

(72) Inventor: Vijay D. Parkhe, San Jose, CA (US)

(21) Appl. No.: 18/943,371

(22) Filed: Nov. 11, 2024

Related U.S. Application Data
(60) Provisional application No. 63/548,363, filed on Nov. 13, 2023.

(51) Int. Cl. H01J 37/32

(52) U.S. Cl. CPC H01J 37/32724; H01J 2237/2007; H01J 2237/20214

(57) ABSTRACT

A processing chamber includes a pedestal hub including a plurality of arms each extending in a different direction. The pedestal hub is rotatable about one or more horizontal axes. The processing chamber further includes a first substrate support operatively coupled to a first arm and a first rotation of the pedestal hub causes the first substrate support to be available to support a substrate. The processing chamber further includes a second substrate support operatively coupled to a second arm and a second rotation of the pedestal hub causes the second substrate support to be available to support the substrate.

### RELATED APPLICATIONS

The present application claims the benefit of U.S. Provisional Patent Application No. 63/548,363, filed Nov. 13, 2023, entitled “SUBSTRATE STRESS MANAGEMENT BASED ON OVERLAY ERROR,” which is incorporated by reference herein.

### TECHNICAL FIELD

Some embodiments of the present disclosure relate, in general, to substrate supports usable in a processing chamber for processing a semiconductor substrate, and in particular to a rotatable pedestal hub that includes multiple substrate supports.

### BACKGROUND

In semiconductor manufacturing, various types of processing chambers are used to perform different steps in the fabrication of semiconductor devices. These chambers are typically found in semiconductor manufacturing equipment, such as chemical vapor deposition (CVD) machines, physical vapor deposition (PVD) machines, and etching tools. Some common types of processing chambers include CVD chambers, PVD chambers, etching chambers, annealing chambers, oxidation chambers, ion implantation chambers, chemical mechanical polishing chambers, photoresist coating chambers, and metrology chambers. Advanced semiconductor manufacturing processes often require a combination of these chambers to create intricate integrated circuits on semiconductor substrates (also referred to as wafers).

Within these processing chambers, chucks are widely used to hold and secure the semiconductor substrates during various substrate processes like etching, deposition, and lithography. The specific type of chuck used depends on the specific semiconductor manufacturing process, including factors such as wafer size, material, temperature sensitivity, and process compatibility. Some commonly used chucks include vacuum chucks, electrostatic chucks, mechanical chucks, magnetic chucks, piezoelectric chucks, wafer carrier chucks, edge grip chucks, heated chucks, and coolant chucks.

### SUMMARY

Some embodiments of the present disclosure described herein cover a processing chamber including a pedestal hub having a plurality of arms each extending in a different direction. The pedestal hub is rotatable about one or more horizontal axes. The processing chamber further includes a first electrostatic chuck operatively coupled to a first arm. A first rotation of the pedestal hub causes the first electrostatic chuck to be available to support a substrate. The processing chamber further includes a second electrostatic chuck operatively coupled to a second arm. A second rotation of the pedestal hub causes the second electrostatic chuck to be available to support the substrate.

Some embodiments of the present disclosure described herein cover a method for processing a substrate. The method may include heating a first electrostatic chuck mounted to a pedestal hub in a processing chamber to a first temperature. The method may further include heating a second electrostatic chuck mounted to the pedestal hub to a second temperature. The method may further include determining that the first temperature of the first electrostatic chuck corresponds to a target temperature for a substrate, and rotating the pedestal hub so that the first electrostatic chuck is oriented to support the substrate. The method may further include placing the substrate on the first electrostatic chuck, and processing the substrate while it is supported on the first electrostatic chuck.

Some embodiments of the present disclosure described herein cover a substrate support assembly including a pedestal hub having a plurality of arms each extending in a different direction. The pedestal hub is rotatable one or more horizontal axes. The substrate support assembly further includes a first chuck operatively coupled to a first arm of the plurality of arms. The first chuck may be heated to a first temperature. The substrate support assembly further includes a second chuck operatively coupled to a second arm of the plurality of arms. The second chuck may be heated to a second temperature that is different from the first temperature.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional side view of one embodiment of a processing chamber including a substrate support assembly;

FIG. 2 depicts a side view of one embodiment of a substrate support assembly including a rotatable pedestal hub and a plurality of arms extending in different directions;

FIG. 3 depicts a top view of one embodiment of a substrate support assembly including a rotatable pedestal hub and a plurality of arms extending in different directions;

FIG. 4 illustrates one embodiment of a method for processing a semiconductor substrate in a processing chamber; and

FIG. 5 illustrates one embodiment of a method for processing a semiconductor substrate in a processing chamber.

### DETAILED DESCRIPTION OF EMBODIMENTS

Processing chambers (also referred to as process chambers) such as CVD chambers, PVD chambers, etching chambers, annealing chambers, oxidation chambers, ion implantation chambers, chemical mechanical polishing chambers, photoresist coating chambers, and metrology chambers generally have a single pedestal that can support a single substrate support. Consequently, the substrate support operates at a single fixed temperature at any given time. Reducing or increasing the temperature of the surface of the substrate support that comes in contact with the substrate can take a few minutes to tens of minutes. As a result, current processing chambers may be slow to respond to temperature changes in a process recipe and/or unsuitable for processes that include fast switching between two or more temperatures.

Embodiments of the present disclosure provide a processing chamber including a pedestal hub that can support two or more chucks or other substrate supports (e.g., heaters), each of which may operate at a different temperature. In some embodiments, the pedestal hub may have two or more arms on which the chucks may be mounted. In some embodiments, the processing chamber may include additional chucks that may be coupled to additional arms of the pedestal hub. For example, the processing chamber may have a pedestal hub with three, four, five, or six arms, each mounting a separate chuck that may be heated to a different temperature. The pedestal hub may be rotatable around one or more horizontal axes so that a chuck with the target temperature is available to support the substrate. The pedestal hub may include a first actuator to move the first arm along a radial direction relative to the pedestal hub. For example, the actuator may move the first arm towards or away from a center of the radial hub.

The pedestal hub and/or each of the arms may include three or more lift pins that may be engaged to lift the substrate away from a mounting surface of the chuck. When a first process (or a first portion of a process) on the substrate is completed, the lift pins may be engaged to lift the substrate away from the mounting surface of the chuck. The processing chamber may include a robotic arm, either mounted on the pedestal hub or inside the process chamber, which may be activated to lift the substrate from the lift pins and move the substrate away from the operating chuck. After the substrate is removed from the lift pins, the lift pins may be retracted. The pedestal hub may be rotated around a horizontal axis so that a second chuck with a new target temperature is available to support the substrate. Lift pins from the pedestal hub may be extended, and the robotic arm may place the substrate on the lift pins of the second chuck. The lift pins of the pedestal hub may retract, causing the substrate to be placed on the surface of the second chuck. The substrate may then be heated to a temperature of the second chuck, which may be substantially different from the temperature of the first chuck.

By moving the substrate between chucks that have each been pre-heated to different temperatures, a time generally spent to ramp up or ramp down a temperature of a chuck or heater during a process may be substantially reduced or eliminated. Accordingly, in embodiments processes that include portions with multiple different temperatures, overall process times may be reduced.

The pedestal hub in embodiments may include a second actuator to move the second arm along the radial direction relative to the pedestal hub. In some embodiments, the pedestal hub may include one or more actuators (e.g., a linear actuator or servo motor) to rotate the arms of the pedestal hub around a horizontal axis.

In some embodiments, a user of the processing chamber may be able to select a specific chuck having a target temperature to be used, and the actuators may rotate the pedestal hub such that the selected chuck with the target temperature is available to support the substrate. In some embodiments, the user may be able to provide a target temperature and the actuators may be able to rotate the pedestal hub such that the chuck having the target temperature is made available to support the substrate. The chucks may each include one or more heating electrodes that may be individually controlled. The heating electrodes from the chucks are connected to the same power source in some embodiments. In some embodiments, the heating electrodes from the chucks are connected to different power sources.

Embodiments of the present disclosure also provide a method for processing a substrate in a process chamber using a recipe that includes large temperature shifts or changes. The method includes heating a first chuck mounted to a pedestal hub in a processing chamber to a first temperature. The method further includes heating a second chuck mounted to the pedestal hub to a second temperature. The method further includes determining that the first temperature of the first chuck corresponds to a target temperature for a substrate, and rotating the pedestal hub so that the first chuck is oriented to support the substrate. The method may further include placing the substrate on the first chuck, and processing the substrate while it is supported on the first chuck. In some embodiments, the chuck is an electrostatic chuck and the substrate may be secured to the chuck by powering clamping electrodes in the chuck.

In some embodiments, the method may further include determining that the second temperature of the second electrostatic chuck corresponds to a second target temperature for the substrate, and removing the substrate from the first chuck. Removing the substrate from the first electrostatic chuck may include extending lift pins in the pedestal hub to lift the substrate, and using a robotic arm or hoop-shaped substrate holder to temporarily hold the substrate while the pedestal hub is rotated. In some embodiments, the method may include disconnecting (e.g., powering off) a power source powering a clamp electrode in the first chuck such that the substrate is not secured to the first chuck. The method may further include rotating the pedestal hub so that the second chuck is oriented to support the substrate. The method further includes extending second lift pins in the pedestal hub and placing the substrate on the second lift pins. The second lift pins are then retracted so that the substrate is in contact with a mounting surface of the second chuck. The method further includes processing the substrate while it is supported on the second chuck that is at the second target temperature.

Embodiments of the present disclosure also provide a substrate support assembly (also referred to as an assembly) including a pedestal hub and a plurality of arms extending from the pedestal hub. The pedestal hub may be rotatable about one or more horizontal axes. The substrate support assembly may include a first chuck operatively coupled to a first arm of the plurality of arms. The first chuck may be heated to a first temperature. The substrate support assembly may further include a second chuck operatively coupled to a second arm of the plurality of arms. The second chuck may be heated to a second temperature different from the first temperature. In some embodiments, the substrate support assembly may include additional chucks that may be coupled to additional arms of the substrate support assembly. For example, the substrate support assembly may have three, four, five, or six arms, each mounting a separate chuck that may be heated to a different temperature.

In embodiments, each chuck on of the substrate support assembly may be a vacuum chuck, an electrostatic chuck, a mechanical chuck, a magnetic chuck, a piezoelectric chuck, a wafer carrier chuck, an edge grip chuck, a heated chuck, or a coolant chuck. In some embodiments, a heater plate is used rather than a chuck. In such embodiments, the substrate may rest on the heater plate, but may not be chucked.

In some embodiments, the substrate support assembly may include a cooling plate, which may be a metal cooling plate or a ceramic cooling plate (also referred to as a dielectric cooling plate), which enhances power dissipation for high temperature processes such as etching. The substrate support assembly may further include a cooling plate (or multiple cooling plates) including one or more cooling loops or channels to circulate a cooling fluid (e.g., a coolant or a refrigerant or gas) and absorb the heat from the puck plate(s). The cooling plate may also include one or more gas channels for a gas (e.g., inert gas) to flow therethrough. The cooling plate may additionally include one or more through holes to accommodate lift pins that may be engaged to lift the substrate away from the puck plate. Similarly, the lift pins may be lowered into the through holes of the cooling plate when disengaged. The cooling plate may also include one or more vias through which one or more terminals connecting the functional elements within the chuck may be connected to a power source. In one embodiment, a separate cooling plate is connected to each chuck. For example, a separate cooling plate may be attached to each arm of the rotatable hub, and a chuck may be coupled to each cooling plate.

In one embodiment, the one or more of the chucks may include one or more puck plates including one or more functional elements. The functional elements may include a clamp electrode, a heating element, a zone heater, a pixelated heater, a radio frequency (RF) electrode, a RF filter, a gas channel, a cooling channel, or combinations thereof. In one embodiment, a puck plate may include one or more clamp electrodes, one or more peripheral RF electrodes, one or more heating elements, such as for a zone heater and/or a pixelated heater, and one or more RF electrodes The chuck may include one or more puck plates that may be bonded by a bonding layer. The bonding layer may include Ni, Ti, C, Si, a flexible graphite layer, an organic elastomer, Al, In, Ni, Ti, and/or an alloy including Ni-Ti or Mo-Mg, or Cu-Ag or Al alloy. Examples of materials that may be used in forming one or more puck plates include niobium, aluminum oxide, aluminum nitride, single crystal alumina, or sapphire.

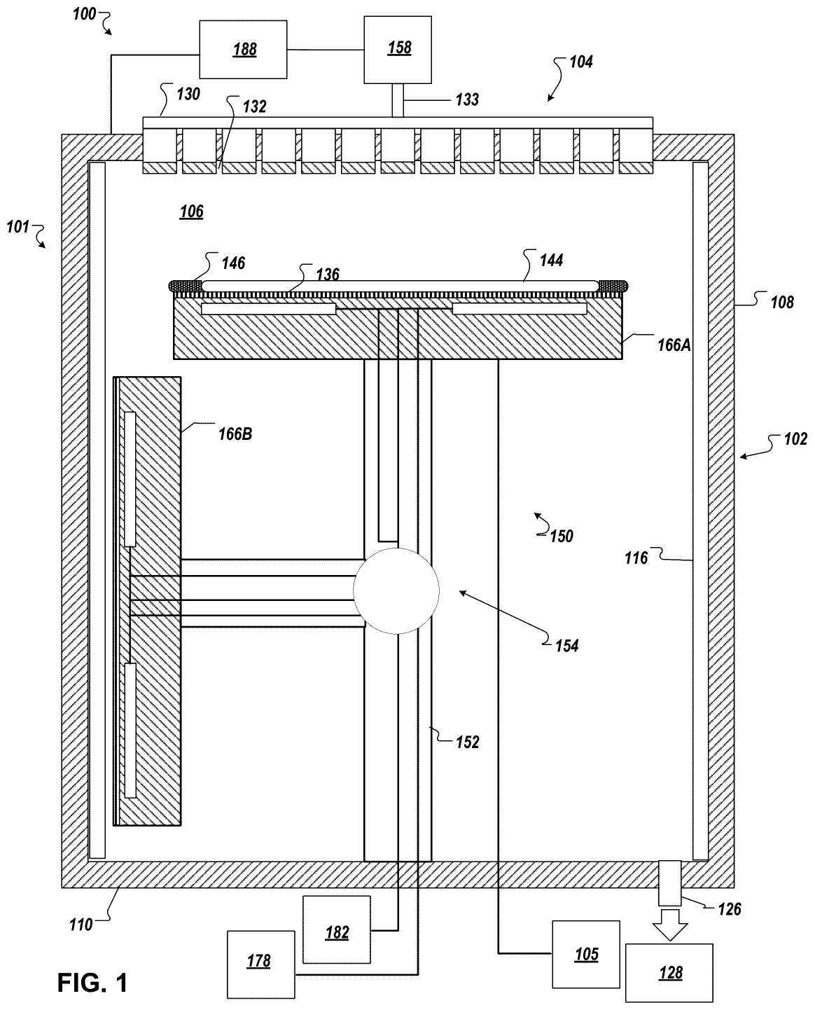

FIG. 1 is a sectional view of a manufacturing system 100 that performs semiconductor processes (e.g., plasma-based processes) in embodiments. The manufacturing system may include a processing chamber 101 coupled to a plasma source 158 via one or more gas delivery lines 133. The processing chamber 101 may be, for example, a plasma etch reactor, a deposition chamber, etc. The processing chamber may be suitable for an etching operation, a deposition operation, a chamber cleaning operation, a plasma treatment operation, or any other type of operation typical of a semiconductor manufacturing facility. In an embodiment, one or more substrates (e.g., wafers) 144 may be provided within the processing chamber 101. In an embodiment, processing chamber 101 may be maintained at a pressure suitable for the target operation. In a particular embodiment, the pressure may be between approximately 1 Torr and approximately 200 Torr. The processing chamber 101 and/or plasma source 158 may be connected to a controller 188, which may control processing of the plasma source 158 and/or processing chamber 101 (e.g., by controlling set points, loading recipes, and so on). In embodiments, the plasma source 158 is a remote plasma source (RPS) that generates plasma at a remote location and delivers the externally generated plasma to the processing chamber 101. Alternatively, the processing chamber 101 may include an integrated plasma source (not shown) that can generate plasma within the processing chamber.

Processing chamber 101 includes a substrate support assembly 150, according to some embodiments. Substrate support assembly 150 includes a rotatable hub 154 to which multiple chucks 166A-B are attached. The rotatable hub 154 may be rotated to cause any one of the multiple chucks to face upwards such that the upwards-facing chuck may support a substrate. The chucks 166A-B may perform chucking operations, e.g., vacuum chucking, electrostatic chucking, etc. Substrate support assembly 150 may further include base plate, cooling plate and/or insulator plate (not shown). In some embodiments, each of the chucks 166A-B is attached to its own dedicated cooling plate (not shown).

Processing chamber 100 includes chamber body 102 and lid 104 that enclose an interior volume 106. Chamber body 102 may be fabricated from aluminum, stainless steel, or other suitable material. Chamber body 102 generally includes sidewalls 108 and a bottom 110. An outer liner 116 may be disposed adjacent to side walls 108, e.g., to protect chamber body 102. Outer liner 116 may be fabricated and/or coated with a plasma or halogen-containing gas resistant material. Outer liner 116 may be fabricated from or coated with aluminum oxide. Outer liner 116 may be fabricated from or coated with yttria, yttrium alloy, oxides thereof, etc.

Exhaust port 126 may be defined in chamber body 102, and may couple interior volume 106 to a pump system 128. Pump system 128 may include one or more pumps, valves, lines, manifolds, tanks, etc., utilized to evacuate and regulate the pressure of interior volume 106.

Lid 104 may be supported on sidewall 108 of chamber body 102. Lid 104 may be openable, allowing access to interior volume 106. Lid 104 may provide a seal for processing chamber 100 when closed. Plasma source 158 may be coupled to processing chamber 100 to provide process, cleaning, backing, flushing, etc., gases and/or plasmas to interior volume 106 through gas distribution assembly 130. Gas distribution assembly 130 may be integrated with lid 104.

Examples of processing gases that may be used in processing chamber 100 include halogen-containing gases, such as C2F6, SF6, SiCl4, HBr, NF3, CF4, CHF3, CH2F3, Cl2 and SiF4. Other reactive gases may include O2 or N2O. Non-reactive gases may be used for flushing or as carrier gases, such as N2, He, Ar, etc. Gas distribution assembly 130 (e.g., showerhead) may include multiple apertures 132 on the downstream surface of gas distribution assembly 130. Apertures 132 may direct gas flow to the surface of substrate 144. In some embodiments, gas distribution assembly may include a nozzle (not pictured) extended through a hold in lid 104. A seal may be made between the nozzle and lid 104. Gas distribution assembly 130 may be fabricated and/or coated by a ceramic material, such as silicon carbide, yttrium oxide, etc., to provide resistance to processing conditions of processing chamber 100.

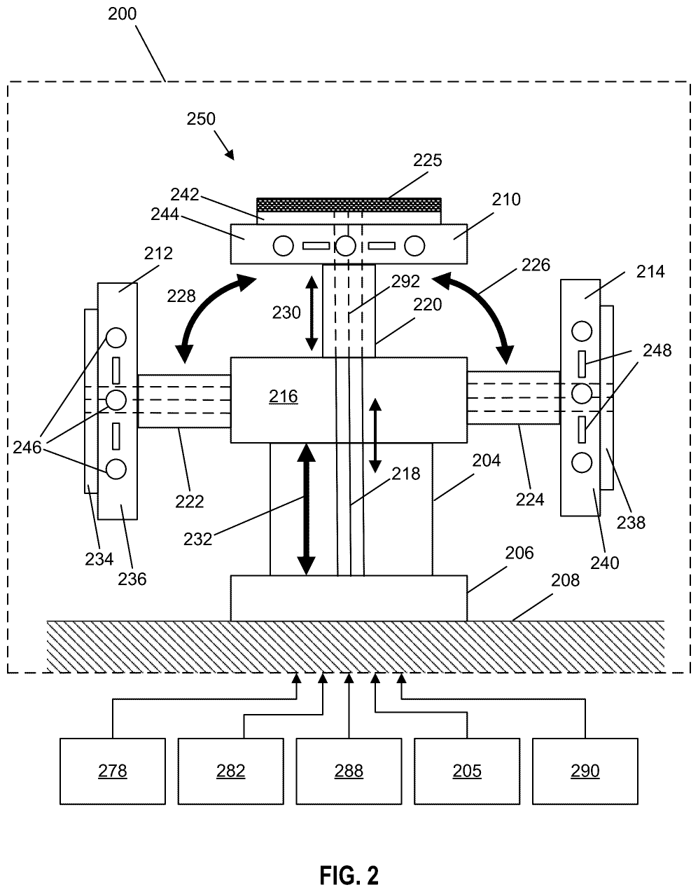

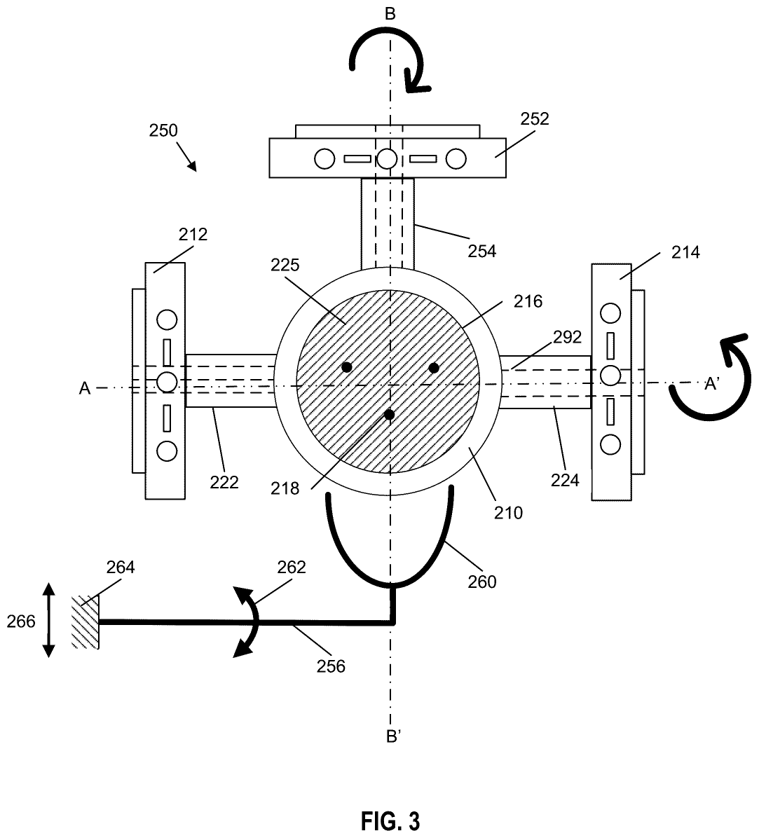

Substrate support assembly 150 may be disposed in interior volume 106 of processing chamber 100 below gas distribution assembly 130. The substrate support assembly 150 may be mounted on a pedestal 152. Any of the chucks 166A-B of substrate support assembly 150 may hold a substrate 144 during processing. Although two chucks 166A-B are illustrated on the rotatable hub 154, as described in further detail below with respect to FIGS. 2 and 3, the processing chamber 100 may include additional chucks (or other substrate supports), which may be mounted on one or more arms of the rotatable hub 154.

Substrate support assembly 150 may include supporting pedestal 152, one or more insulator plate, one or more base plate, one or more cooling plate, and pucks 166A-B. Pucks 166A-B may include electrodes 536 for providing one or more functions. Electrodes 536 may include chucking electrodes (e.g., for securing substrate 144 to an upper surface of puck 166), heating electrodes, RF electrodes for plasma control, etc.

A protective ring 146 may be disposed over a portion of one or more of the pucks 166A-B at an outer perimeter of puck 166A-B. Puck 166A-B may be coated with a protective layer (not shown). The protective layer may be a ceramic such as Y2O3 (yttria or yttrium oxide), Y4Al2O9 (YAM), Al2O3 (alumina), Y3Al5O12 (YAG), YAlO3 (YAP), quartz, SiC (silicon carbide), Si3N4 (silicon nitride), Sialon, AlN (aluminum nitride), AlON (aluminum oxynitride), TiO2 (titania), ZrO2 (zirconia), TiC (titanium carbide), ZrC (zirconium carbide), TiN (titanium nitride), TiCN (titanium carbon nitride), Y2O3 stabilized ZrO2 (YSZ), and so on. The protective layer may be a ceramic composite such as YAG distributed in an alumina matrix, a yttria-zirconia solid solution, a silicon carbide-silicon nitride solid solution, or the like. The protective layer may be sapphire or MgAlON.

Pucks 166A-B may further include multiple gas passages such as grooves, mesas, and other features that may be formed in an upper surface of pucks 166A-B. Gas passages may be fluidly coupled to a gas source 105. Gas from gas source 105 may be utilized as a heat transfer or backside gas. One or more linear servo motors or stepper motors may be utilized for control of one or more lift pins of pucks 166A-B, etc. Multiple gas sources may be utilized (not shown). Gas passages may provide a gas flow path for a backside gas such as He via holes drilled in pucks 166A-B. Backside gas may be provided at a controlled pressure into gas passages to enhance heat transfer between pucks 166A-B and substrate 144.

Pucks 166A-B may include one or more clamping electrodes. The clamping electrodes may be controlled by chucking power source 182. Clamping electrodes may further couple to one or more RF power sources through a matching circuit for maintaining a plasma formed from process and/or other gases within processing chamber 100. The RF power sources may be capable of producing an RF signal having a frequency from about 50 kilohertz (kHz) to about 3 gigahertz (GHz) and a power of up to about 10,000 Watts. Heating electrodes of pucks 166A-B may be coupled to heater power source 178.

Controller 188 may control one or more parameters and/or set points of the plasma source 158 and/or processing chamber 101, including one or more parameters of rotatable hub 154. Controller 188 can be and/or include a computing device such as a personal computer, a server computer, a programmable logic controller (PLC), a microcontroller, and so on. Controller 188 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. Controller 188 can include a data storage device (e.g., one or more disk drives and/or solid state drives), a main memory, a static memory, a network interface, and/or other components. Controller 188 can execute instructions to perform any one or more of the methodologies and/or embodiments described herein. For example, controller 188 may control one or more actuators to rotate rotatable hub 154 and control which chuck 166A-B is available to support a substrate. Additionally, controller 188 may control temperature setpoints for each of the chucks 166A-B. The instructions executed by controller 188 can be stored on a computer readable storage medium, which can include the main memory, static memory, secondary storage and/or processing device (during execution of the instructions).

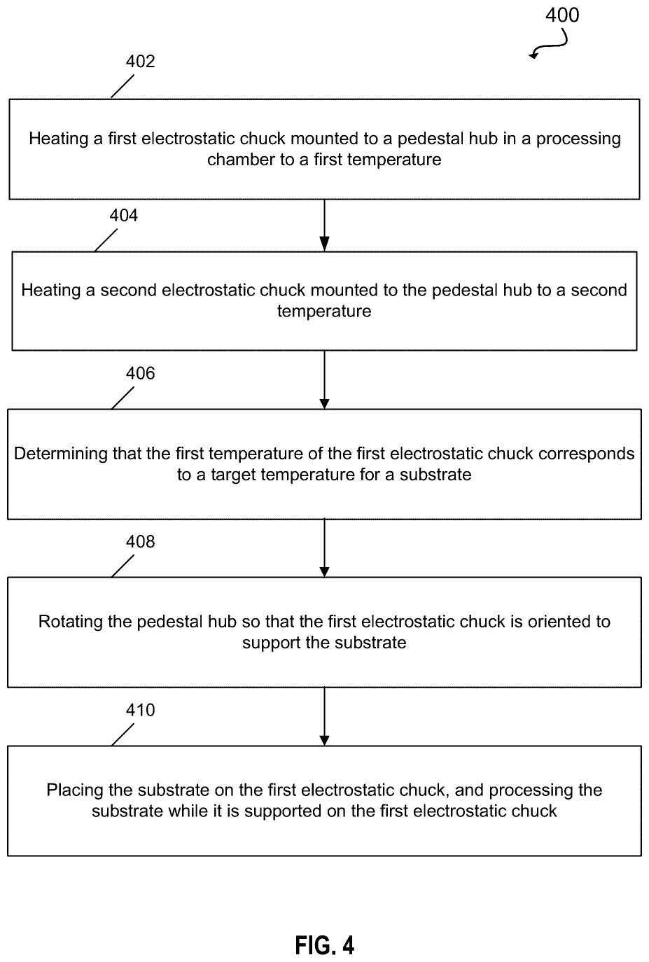

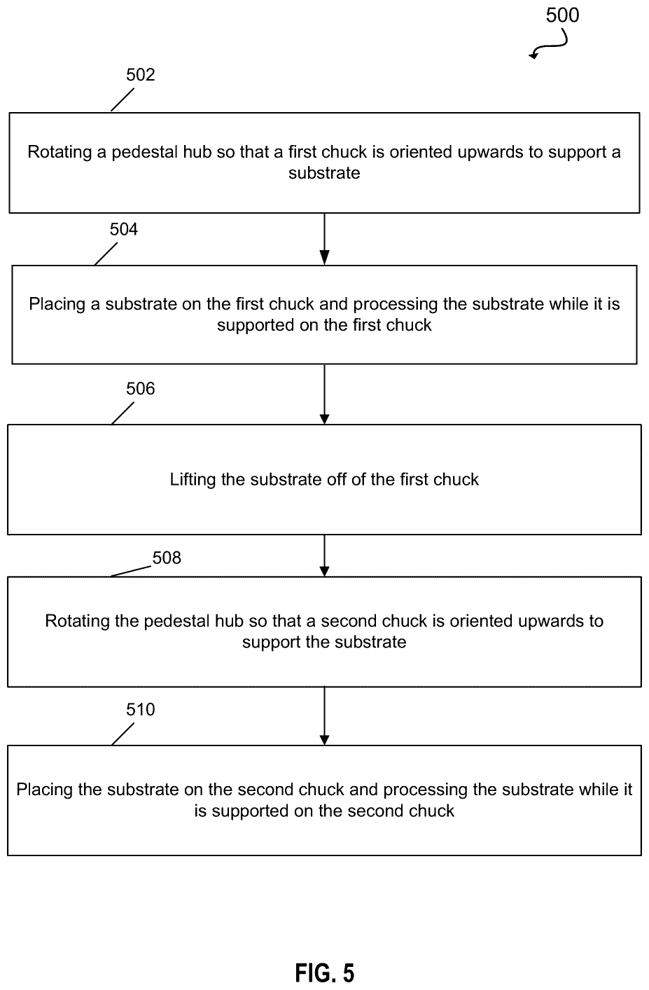

In embodiments, execution of the instructions by controller 188 causes controller 188 to perform the methods of FIG. 4 and/or FIG. 5. For example, controller 188 may determine that the chuck 166A is to be replaced with chuck 166B because chuck 166B has a target temperature. The controller 188 may rotate the rotatable hub 154 such that a mounting surface in the chuck 166B is properly positioned to receive a substrate. In some embodiments, the controller 188 may receive a user input (e.g., either manual or computer-generated) to replace the chuck 166A with another chuck (e.g., with chuck 166B). The controller 188 may, upon receiving the input, rotate the rotatable hub 154 such that a mounting surface in the chuck 166B is properly positioned to receive a substrate. Controller 188 can also be configured to permit entry and display of data, operating commands, and the like by a human operator.

FIG. 2 depicts a side view of a processing chamber 200, according to some embodiments. The processing chamber 200 may be a CVD chamber, a PVD chamber, an etching chamber, an annealing chamber, an oxidation chamber, an ion implantation chamber, a chemical mechanical polishing chamber, a photoresist coating chamber or a metrology chamber. For the purposes of illustration, an etching chamber is described here. The processing chamber 200 may include a substrate support assembly 250 having a pedestal hub 216 that can support two or more chucks. In the example implementation illustrated in FIG. 2, chucks 210, 212, 214 are shown as being supported by the pedestal hub 216. However, a fourth chuck (not seen here) is shown in FIG. 3, which illustrates a top view of the substrate support assembly 250. Chucks 210, 212, 214 may include any chuck that may be used in a semiconductor manufacturing process. Additionally, heaters may be used instead of one or more of the chucks. Examples include vacuum chucks, electrostatic chucks, mechanical chucks, magnetic chucks, piezoelectric chucks, wafer carrier chucks, edge grip chucks, heated chucks, and coolant chucks. In some embodiments, separate heating and/or cooling assemblies are provided for each chuck 210, 212, 214. For example, chuck 210 may be mounted to a first cooling plate on arm 220, chuck 212 may be mounted to a second cooling plate on arm 222, and chuck 214 may be mounted to a third cooling plate on arm 224.

For the purposes of illustration, electrostatic chucks (ESC) are shown in FIG. 2. Chuck 210 may include a puck plate assembly 242, which may be bonded to a cooling plate 244. Chuck 212 may include a puck plate assembly 234, which may be bonded to a cooling plate 236. Chuck 214 may include a puck plate assembly 238, which may be bonded to a cooling plate 240. Each combination of a chuck, an associated cooling plate, and/or one or more additional associated plates may be referred to as a substrate support sub-assembly. Accordingly, in embodiments substrate support assembly 250 may include multiple substrate support sub-assemblies.

Puck plates 242, 234, and 238 may include one or more plates with one or more functional elements embedded in each of them. In one embodiment, a puck plate may include one or more clamp electrodes, one or more peripheral RF electrodes, one or more heating elements, such as for a zone heater and/or a pixelated heater, and one or more RF electrodes. Clamping electrodes may further couple to one or more RF power sources through a matching circuit for maintaining a plasma formed from process and/or other gases within processing chamber 200. The RF power sources may be capable of producing an RF signal having a frequency from about 50 kilohertz (kHz) to about 3 gigahertz (GHz) and a power of up to about 10,000 Watts. The heating electrodes may be connected to a power source 278 via terminals that may be routed through the pedestal hub 216 to reach the respective chucks 210, 212, and 214. Similarly, the clamp electrodes may be connected to a power source 282 via terminals that may be routed through the pedestal hub 216 to reach the respective chucks 210, 212, and 214. In some embodiments, the clamp electrodes and the heating electrodes may be connected to the same power source.

The chucks 210, 212, 214 may further include or be associated with cooling plates 244, 236, 240 including one or more cooling loops or channels 246 to circulate a cooling fluid (e.g., a coolant or a refrigerant or gas) and absorb the heat from the puck plates. The cooling loops or channels 246 may be connected to a cooling source 290 that may supply a cooling fluid to regulate a temperature of the cooling plate. Additionally, the cooling plates 244, 236, 240 may also include one or more gas channels 248 for a gas (e.g., inert gas) to flow therethrough. The gas channels 248 may be connected to a gas source 205 that may supply a gas (e.g., He) to the cooling plate. Gas from gas source 205 may be utilized as a heat transfer or backside gas. One or more linear servo motors or stepper motors may be utilized for control of one or more lift pins of puck, etc. Multiple gas sources may be utilized (not shown). Gas passages may provide a gas flow path for a backside gas such as He via holes drilled in puck. Backside gas may be provided at a controlled pressure into gas passages to enhance heat transfer between puck and substrate 225. The gas lines connecting the gas source 205 to the gas channels 248 may include a flexible metal bellow, a flexible polymeric bellow, or a flexible rubber tubing.

The individual arms 220, 222, 224 and the cooling plates 244, 236, 240 may additionally include one or more through holes 292 to accommodate lift pins 218 that may be engaged to lift a substrate 225 away from the puck plate. Similarly, the lift pins may be lowered into the through holes 292 of the individual arms 220, 222, 224 and the cooling plates 244, 236, 240 when disengaged. The cooling plates 244, 236, 240 may also include one or more vias through which one or more terminals connecting the functional elements within the chuck may be connected to a power source (e.g., power source 278 or 282). The puck plate assemblies 242, 234, 238 may include one or more puck plates that may be bonded by a bonding layer. The bonding layer may include Ni, Ti, C, Si, a flexible graphite layer, an organic elastomer, Al, In, Ni, Ti, and/or an alloy including Ni-Ti or Mo-Mg, or Cu-Ag or Al alloy. Examples of materials that may be used in forming one or more puck plates include niobium, aluminum oxide, aluminum nitride, single crystal alumina, or sapphire. The puck plates of the chucks 210, 212, 214 may be formed of the same ceramic material, different ceramic materials, the same ceramic material with different purities, the same ceramic material with different grain sizes, different ceramic materials with different grain sizes, or different ceramic materials with different purities.

Each of the chucks 210, 212, 214 may operate at a different temperature. In some embodiments, all the chucks 210, 212, 214 may operate at the same temperature. Pedestal hub 216 may include arms 220, 222, 224 on which the chucks 210, 212, 214 may be mounted, respectively. In some embodiments, the processing chamber may include additional chucks that may be coupled to additional arms of the pedestal hub 216. For example, the processing chamber 200 may have three, four, five, or six arms, each mounting a separate chuck that may be heated to a different temperature. The lift pins 218 may be housed inside the pedestal hub 216 and may be engaged lift a substrate 225 away from the puck plate on which it is mounted. In some embodiments, the lift pins may be housed in the individual arms 220, 222, 224. The lift pins 218 may be actuated by one or more linear actuators (e.g., servo motors or stepper motors), which may be housed in the body of the pedestal hub 216 and/or the arms 220, 222, 224. The pedestal hub 216 may be rotatable around one or more horizontal axes so that a target chuck with a target temperature is available to support the substrate 225. The pedestal hub 216 may house one or more such actuators that enable the pedestal hub 216 to rotate around one or more horizontal axes. For example, the pedestal hub 216 may include a first actuator to move arm 220 along a radial direction relative to the pedestal hub 216. Similarly, the pedestal hub 216 may include a second actuator to move arm 222 along a radial direction relative to the pedestal hub 216, a third actuator to move arm 224 along a radial direction relative to the pedestal hub 216, so on and so forth.

When a first process (e.g., etching or deposition process) on the substrate 225 is completed and/or when one or more steps of the first process are completed, the lift pins 218 may be engaged to lift the substrate 225 away from the mounting surface of the chuck 210. The processing chamber 200 may include a robotic arm, either mounted on the pedestal hub 216 or on the walls of the process chamber (e.g., sidewalls 108), which may be activated to lift the substrate 225 from the lift pins 218 and move the substrate 225 away from the operating chuck 210. The pedestal hub 216 may then be rotated around a horizontal axis (e.g., along arrow 226) so that a second target chuck 212 or 214 with the target temperature is available to support the substrate 225. The substrate 225 may then be placed on the now vertically-facing or upright chuck for further processing (e.g., for one or more additional steps of the process that are to be performed at a second temperature of the second chuck that is different from a first temperature of the first chuck).

In some embodiments, the pedestal hub may include one or more actuators (e.g., a linear actuator or servo motor) to rotate the arms 220, 222, 224 of the pedestal hub around a horizontal axis. The arms 220, 222, 224 may be movable in a vertical direction 230 when the respective arm is in an upright position.

The processing chamber 200 may further include a chamber mount 206 that may be operatively coupled to the pedestal hub 216 via a neck portion 204. The neck portion 204 may be configured to move in a vertical direction 232 so that the pedestal hub 216 may be lowered. The chamber mount 206 may be configured to mount the pedestal hub 216 onto a base 208 of the processing chamber 200. In some embodiments, a user of the processing chamber 200 may be able to select a specific chuck and the actuators may be able to rotate the pedestal hub 216 such that the selected chuck with the target temperature is available to support the substrate. In some embodiments, the user may be able to provide a target temperature (e.g., 100° C.) and the actuators may be able to rotate the pedestal hub such that the chuck having the target temperature (e.g., 100° C.) is made available to support the substrate 225.

Controller 288 may control motion of arms 220, 222, 224 to perform one or more processes in processing chamber 200. Controller 288 can correspond to controller 188 of FIG. 1 in embodiments. In embodiments, execution of the instructions by controller 288 causes controller 288 to perform the methods of FIG. 4 or FIG. 5. For example, controller 288 may determine that chuck 210 is to be replaced with another chuck 212, 214 because the other chuck has a target temperature. The controller 288 may rotate the pedestal hub 216 such that a mounting surface in the other chuck 212, 214 is properly positioned to receive a substrate 225. In some embodiments, the controller 288 may receive a user input (e.g., either manual or computer-generated) to replace the chuck 210 with another chuck 212, 214 because the other chuck has a target temperature. The controller 288 may, upon receiving the input, rotate the pedestal hub 216 such that a mounting surface in the other chuck 212, 214 is properly positioned to receive the substrate 225. Controller 288 can also be configured to permit entry and display of data, operating commands, and the like by a human operator.

FIG. 3 depicts a top view the substrate support assembly 250, including a rotatable pedestal hub 216 and a plurality of arms 222, 254, 224 extending in different directions. As shown in this figure, the pedestal hub 216 may be connected to a fourth arm 254, which may mount another chuck 252. The pedestal hub 216 may be rotatable around a first horizontal axis A-A′ and a second horizontal axis B-B′ in some embodiments. The process chamber may include a robotic arm 256, which may be mounted to the pedestal hub 216 or a sidewall 264 of the process chamber. The robotic arm 256 may include a hoop-shaped substrate holder 260. The robotic arm 256 may be movable or rotatable around a vertical axis along arrow 262. The hoop-shaped substrate holder 260 may be configured to carry the substrate 225 away from the mounting surface of an operating chuck. The robotic arm 256 may be directly or indirectly controlled by controller 288 shown in FIG. 2. In some embodiments, the robotic arm 256 may be movable in a vertical direction and/or horizontal direction 266.

In some embodiments, the processing chamber may further include a shield or a process kit ring that may be mounted on a sidewall 264 of the processing chamber. The shield or process kit ring may be configured to at least partially support a wafer or substrate when a mounting surface of the chuck is retracted. The shield or process ring kit may be made of a metal or a polymeric material. The shield or process kit ring may be used to support the wafer in embodiments where the pedestal hub is movable in a vertical direction 232.

When a first process (e.g., etching or deposition) on the substrate 225 is completed, the lift pins 218 may be engaged to lift the substrate 225 away from the mounting surface of the chuck 210. The robotic arm 256 may then be activated to lift the substrate 225 from the lift pins 218 and move the substrate 225 away from the operating chuck 210. The pedestal hub 216 may then be rotated around a horizontal axis (e.g., along axis A-A′) so that a second target chuck 252 with the target temperature is available to support the substrate 225. In a further example, the pedestal hub 216 may further be rotated around another horizontal axis (e.g., along axis B-B′) so that a second target chuck 212 with the target temperature is available to support the substrate 225.

In some embodiments, axis A-A′ may be perpendicular to axis B-B′. In some embodiments, axis A-A′ may be at an angle to axis B-B′. Although some degrees of freedom are illustrated in the figures, the pedestal hub 216 and/or the arms attached thereto may have additional degrees of freedom to move the chucks around the substrate support assembly 250. In some embodiments, the pedestal hub may include one or more actuators (e.g., a linear actuator or servo motor) to rotate the arms 254, 222 of the pedestal hub around the horizontal axis. In some embodiments, a user of the processing chamber may be able to select a specific chuck and the actuators may be able to rotate the pedestal hub 216 such that the selected chuck with the target temperature is available to support the substrate. In some embodiments, the user may be able to provide a target temperature (e.g., 100° C.) and the actuators may be able to rotate the pedestal hub such that the chuck having the target temperature (e.g., 100° C.) is made available to support the substrate 225.

FIG. 4 illustrates one embodiment of a method 400 for processing a semiconductor substrate in a processing chamber (e.g., processing chamber 200). At block 402, the method may include heating a first substrate support (e.g., chuck 210) mounted to a pedestal hub (e.g., pedestal hub 216) in a processing chamber (e.g., processing chamber 200) to a first temperature. The temperature to which an operating substrate support may be heated may depend on one more process parameters of the process that the substrate (e.g., substrate 225) is undergoing. For example, etching may use a higher temperature for an operating substrate support when compared to deposition. Additionally, a single process (e.g., a single etch process or deposition process) may include multiple steps, each of which may use different temperature setpoints. For such processes that use multiple different temperature setpoints, it can take time for a substrate support to transition from a first temperature setpoint to a second temperature setpoint. Such transition times can become particularly problematic for processes that alternate between different temperature setpoints multiple times during execution of the processes. For example, some processes may include alternating between a high temperature setpoint and a low temperature setpoint. In a traditional substrate support assembly, each transition between a high temperature setpoint and a low temperature setpoint may take considerable time (e.g., minutes to tens of minutes). In embodiments, multiple different substrate supports are maintained at different temperatures, and during execution of a process the substrate may be moved between the substrate supports at the different temperature setpoints, greatly reducing an overall process time.

At block 404, the method further includes heating a second substrate support (e.g., chucks 212, 214, 254) mounted to the pedestal hub 216 to a second temperature. For example, a process such as etching may call for the substrate to quickly switch from a low temperature (e.g., 70° C.) to a high temperature (e.g., 150° C.). In this example, the substrate may be moved from the lower temperature to the higher temperature by moving the substrate from the first substrate support to the second substrate support. Similarly, if the substrate is to be moved from the higher temperature to the lower temperature, then the substrate may be moved from the second substrate support to the first substrate support. The target temperature may depend on one or more process parameters of the process the substrate is undergoing.

At block 406, the method includes determining that the first temperature of the first substrate support corresponds to a target temperature for the substrate. When such a determination is made, the substrate is removed from the second substrate support. Removing the substrate from the second electrostatic chuck may include extending lift pins (e.g., lift pins 218) in the pedestal hub to lift the substrate and using a robotic arm or hoop-shaped substrate holder to temporarily hold the substrate while the pedestal hub is rotated. In some embodiments, the method may include disconnecting (e.g., powering off) a power source powering a clamp electrode in a puck plate such that the substrate is not secured to the puck plate anymore. At block 408, the method involves rotating the pedestal hub so that the first substrate support, or whichever substrate support has the target temperature, is oriented to support the substrate. At block 410, the method may include placing the substrate on the first substrate support, and processing the substrate while it is supported on the first substrate support. In some embodiments, the substrate may be secured to the substrate support by connecting or powering back the clamp electrodes in the substrate support.

In some embodiments, the method may further include determining that the second temperature of the second substrate support corresponds to a second target temperature for the substrate. When such a determination is made, the substrate is removed from the first substrate support. Removing the substrate from the first substrate support may include extending lift pins in the pedestal hub to lift the substrate and using a robotic arm or hoop-shaped substrate holder to temporarily hold the substrate while the pedestal hub is rotated. In some embodiments, the method may include disconnecting (e.g., powering off) a power source powering a clamp electrode in a puck plate such that the substrate is not secured to the puck plate anymore. The method may further include rotating the pedestal hub so that the second substrate support is oriented to support the substrate. The method further includes extending second lift pins in the pedestal hub and placing the substrate on the second lift pins. The second lift pins are then retracted so that the substrate is in contact with the mounting surface of the second substrate support. In some embodiments, the substrate may be secured to the puck plate by connecting or powering back the clamp electrodes in the puck plate. The method further includes processing the substrate while it is supported on the second substrate support. In embodiments, one or more substrates are automatically replaceable without any manual intervention.

FIG. 5 illustrates one embodiment of a method 500 for processing a

semiconductor substrate in a processing chamber (e.g., processing chamber 200). At block 502, the method may include rotating a pedestal hub (e.g., pedestal hub 216) in a processing chamber (e.g., processing chamber 200) so that a first chuck (e.g., chuck 210) is oriented upwards to support a substrate. The temperature to which the first chuck may be heated may depend on one more process parameters of the process that the substrate (e.g., substrate 225) is undergoing. For example, etching may require a higher temperature for an operating chuck when compared to deposition. Similarly, lithography may require a different temperature for the operating chuck. At block 504, the method 500 placing a substrate on the first chuck. This may involve activating the lift pins such that the lift pins in the pedestal hub are in an extended position and ready to receive the substrate. After the substrate is received, the lift pins are lowered such that the substrate is supported by a mounting surface of the first chuck. Block 504 may also involves processing the substrate while it is supported on the first chuck. For example, if a deposition process is to be performed, then the first chuck may be heated to a first temperature before placing the substrate on the mounting surface. Similarly, etching may require the first chuck to be heated to a different temperature. After the process operation has been completed, method 500 may involve lifting the substrate off the first chuck at block 506. This may involve powering off or disconnecting clamp electrodes that are holding the substrate against the first chuck. Block 506 may further involve activating the lift pins such that the lift pins (e.g., lift pins 218) in the pedestal hub are in an extended position and substrate is now separated from the first chuck. The substrate is then removed from the first chuck using a robotic arm or hoop-shaped substrate holder, which may temporarily hold the substrate while the pedestal hub is rotated. At block 508, the method may involve rotating the pedestal hub so that a second chuck, or whichever chuck has the target temperature, is now oriented upwards to support the substrate. At block 510, the method may include placing the substrate on the second chuck. This may involve activating the lift pins such that the lift pins in the pedestal hub are in an extended position and ready to receive the substrate. The robotic arm or hoop-shaped substrate holder may then place the substrate on the lift pins, and after the substrate is received, the lift pins are lowered such that the substrate is supported by a mounting surface of the second chuck. Block 510 may further include processing the substrate while it is supported on the second chuck. In some embodiments, the substrate may be secured to the puck plate by connecting or powering back the clamp electrodes in the puck plate. In embodiments described above, one or more substrates are automatically replaced without any manual intervention.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner. In one embodiment, multiple metal bonding operations are performed as a single step.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

1. A processing chamber comprising:
a pedestal hub comprising a plurality of arms each extending in a different direction, wherein the pedestal hub is rotatable about one or more horizontal axes;
a first substrate support coupled to a first arm of the plurality of arms, wherein a first rotation of the pedestal hub causes the first substrate support to be available to support a substrate; and
a second substrate support operatively coupled to a second arm of the plurality of arms, wherein a second rotation of the pedestal hub causes the second substrate support to be available to support the substrate.

2. The processing chamber of claim 1, further comprising:
a chamber mount operatively coupled to the pedestal hub, the chamber mount configured to mount the pedestal hub onto a base of the processing chamber.

3. The processing chamber of claim 2, further comprising:
an actuator to move the chamber mount along a vertical direction.

4. The processing chamber of claim 1, wherein the first substrate support is a first electrostatic chuck that comprises a first chucking electrode and a first heating element to be heated to a first temperature and the second substrate support is a second electrostatic chuck that comprises a second chucking electrode and a second heating element to be heated to a second temperature.

5. The processing chamber of claim 1, further comprising:
a first actuator to move the first arm along a radial direction relative to the pedestal hub; and
a second actuator to move the second arm along the radial direction relative to the pedestal hub.

6. The processing chamber of claim 5, further comprising:
a shield mounted on a wall of the processing chamber, the shield configured to support a wafer disposed on a mounting surface of the first substrate support or the second substrate support.

7. The processing chamber of claim 1, further comprising:
one or more gas lines connecting to at least one of the first substrate support or the second substrate support, wherein the one or more gas lines are to carry a gas to at least one of the first substrate support or the second substrate support.

8. The processing chamber of claim 7, wherein the one or more gas lines comprise at least one of a flexible metal bellow, a flexible polymeric bellow, or a flexible rubber tubing.

9. The processing chamber of claim 1, further comprising:
one or more cooling lines connecting to the at least one of the first substrate support or the second substrate support, wherein the one or more cooling lines are to carry a cooling fluid to at least one of the first substrate support or the second substrate support.

10. The processing chamber of claim 1, wherein the pedestal hub further comprises a first plurality of lift pins movable in a vertical direction, the first plurality of lift pins configured to lift a substrate from a mounting surface of the first substrate support.

11. The processing chamber of claim 10, further comprising:
a first hoop-shaped substrate holder rotatable around a second axis, the first hoop-shaped substrate holder configured to carry the substrate away from the mounting surface of at least one of the first substrate support or the second substrate support.

12. A method comprising
heating a first substrate support mounted to a pedestal hub in a processing chamber to a first temperature;
heating a second substrate support mounted to the pedestal hub to a second temperature;
determining that the first temperature of the first substrate support corresponds to a target temperature for a substrate;
rotating the pedestal hub so that the first substrate support is oriented to support the substrate;
placing the substrate on the first substrate support; and
processing the substrate while it is supported on the first substrate support.

13. The method of claim 12, further comprising:
determining that the second temperature of the second substrate support corresponds to a second target temperature for the substrate;
removing the substrate from the first substrate support;
rotating the pedestal hub so that the second substrate support is oriented to support the substrate;
placing the substrate on the second substrate support; and
further processing the substrate while it is supported on the second substrate support.

14. The method of claim 13, wherein removing the substrate from the first substrate support comprises extending first lift pins in the pedestal hub to lift the substrate and using a robotic arm or hoop-shaped substrate holder to retrieve the substrate from the first lift pins and temporarily hold the substrate while the pedestal hub is rotated.

15. The method of claim 14, wherein placing the substrate on the second substrate support comprises extending second lift pins in the pedestal hub, placing the substrate on the second lift pins by the robotic arm or the hoop-shaped substrate holder, and retracting the second lift pins.

16. A substrate support assembly comprising:
a pedestal hub comprising a plurality of arms each extending in a different direction, wherein the pedestal hub is rotatable about a first horizontal axis;
a first chuck operatively coupled to a first arm of the plurality of arms, wherein the first chuck is heated to a first temperature; and
a second chuck operatively coupled to a second arm of the plurality of arms, wherein the second chuck is heated to a second temperature different from the first temperature.

17. The substrate support assembly of claim 16, wherein a first rotation of the pedestal hub causes the first chuck to be available to support a substrate, and a second rotation of the pedestal hub causes the second chuck to be available to support the substrate.

18. The substrate support assembly of claim 16, wherein the pedestal hub is rotatable around a second horizontal axis that is perpendicular to the first horizontal axis.

19. The substrate support assembly of claim 16, wherein the pedestal hub comprises a plurality of first lift pins movable in a vertical direction, the plurality of first lift pins configured to lift a substrate from a mounting surface of the first chuck, or the pedestal hub comprises a plurality of second lift pins movable in the vertical direction, the plurality of second lift pins configured to lift the substrate from a mounting surface of the second chuck.

20. The substrate support assembly of claim 19, further comprising:
a first hoop-shaped substrate holder rotatable around a vertical axis, the first hoop-shaped substrate holder configured to carry the substrate away from the mounting surface of the first chuck or the second chuck.
